(19) United States
(12) Patent Application Publication
(10) Pub. No.: US 2002/0173072 A1
(43) Pub. Date: Nov. 21, 2002

(54) Data capture plate for substrate components

(76) Inventor: Thane M. Larson, Roseville, CA (US)

Correspondence Address: HEWLETT-PACKARD COMPANY, Intellectual Property Administration, P.O. Box 272400, Fort Collins, CO, 80527-2400, US

(21) Appl. No.: 09/860,901

(22) Filed: May 18, 2001

(51) Int. Cl. H01L 21/44

(52) U.S. Cl. 438/107; 257/684

(57) ABSTRACT

A method and apparatus to mount a data capture plate to a substrate, under a component. One embodiment of the invention involves a method to assemble a data capture plate on a substrate. A second embodiment of the invention involves a method to fabricate a data capture plate. A third embodiment of the invention involves an assembled substrate including a data capture plate on the second side of the assembled substrate, under an electrical contact area of a component on the first side of the assembled substrate.

### CROSS-REFERENCE TO CO-PENDING APPLICATIONS

This application is related to the co-pending U.S. patent application entitled “Capacitor Plate for Substrate Components,” filed on May 18, 2001, by the common assignee, which is hereby incorporated by reference.

### BACKGROUND OF THE INVENTION

1. Field of the Invention

This invention relates generally to a data capture plate to provide a resistive, high capacitance, and low inductance test probe interface for a substrate with integrated circuit (IC) components, and more specifically relates to a data capture plate to provide a test probe interface for a printed circuit board assembled with one or more land grid array (LGA) or ball grid array (BGA) IC components.

2. Description of the Prior Art

In many data processing systems (e.g., computer systems, programmable electronic systems, telecommunication switching systems, control systems, and so forth) very large pin count electrical components (e.g., application specific integrated circuits and processor chips) are assembled on substrates (e.g., printed circuit boards, other flexible substrates, multi-chip modules, and equivalents). One type of packaging that is frequently used for a very large pin count electrical component is what is commonly known as a LGA component. Electrical connections between the LGA component pins and the corresponding conductive pads on the substrate are frequently achieved by compressing an elastomeric insulating material containing several perpendicular conductive channels (e.g., vias filled with conductive balls or conductive threads). In order to achieve reliable electrical connection between the pins and the pads, these LGA components are normally clamped by metal brackets and bolts to the substrate. BGA components are typically soldered to the substrate, and do not need clamping.

As the operating frequencies of LGA components, BGA components, and other IC components increase, test probe interface loading becomes more of a problem, since a test probe typically has considerable stray inductance. Test probe interface capacitance and resistance are typically needed to reduce detrimental effects, especially on high frequency, low impedance busses. Ideally, the test probe interface capacitance and resistance should be distributed as close to the IC components as possible to reduce stray inductance.

One method that is common is the attachment of capacitors 112 and impedance matching resistors 114 on the substrate 104 outside the footprint perimeter of an IC component 106. FIG. 1 illustrates a conventional test probe interface with capacitors 112 and resistors 114 assembled on a printed circuit board (PCB) 104, outside the perimeter of a LGA or BGA component 106 assembled on the PCB 104. A LGA component 106 is electrically connected to the substrate 104 through the substrate electrical contact area 108 and an interposer (e.g., a socket, an elastomeric pad with conductive vias, or an equivalent connector) 110. Alternatively, a BGA component (not shown) is soldered to the substrate 104. The substrate 104 also has a substrate electrical contact area 102 that is normally used for In-Circuit Testing (ICT) of the assembled substrate.

However, attaching capacitors and resistors to a substrate outside the footprint perimeter of IC components increases the inductance that is seen by the IC component pins, and reduces the filtering of high frequency noise on power and ground lines of the substrate seen by the IC component and by an electrically connected test probe. Without an improved test probe interface to provide matched impedance with a relatively low inductance, discrete capacitors and discrete resistors with relatively high inductance will limit the effectiveness of test probes as the IC component operating frequencies increase, possibly resulting in operational failures during testing.

It would be desirable to provide an improved test probe interface with relatively low inductance, and minimize the loading on an IC component by electrically connecting a test probe.

### SUMMARY OF THE INVENTION

The present invention provides a data capture plate that can provide an improved test probe interface to provide tip resistance and capacitance, with relatively low inductance, and minimize the loading on an IC component by electrically connecting a test probe.

A first aspect of the invention is directed to a method to assemble a data capture plate to one side of a substrate having a first side with a first electrical contact area, and a second side with a second electrical contact area. The method includes connecting a component to the first electrical contact area on the first side of said substrate; and connecting the data capture plate to the second electrical contact area on the second side, opposite the first electrical contact area on the first side of the substrate.

A second aspect of the invention is directed to a method to fabricate a data capture plate. The method includes selecting a set of physical specifications of the data capture plate; estimating an initial required resistance and capacitance for a plurality of contacts on the data capture plate; modeling the data capture plate after assembly on a substrate; estimating a more precise required resistance and capacitance for the plurality of contacts on the data capture plate after modeling the data capture plate after assembly on the substrate; and fabricating the data capture plate according to the set of physical specifications.

A third aspect of the invention is directed to an assembled substrate including a data capture plate. The assembled substrate has a first side and a second side, and a first electrical contact area on the first side and a second electrical contact area on the second side; an electrical component having a plurality of leads electrically connected to the first electrical contact area of the substrate; and a data capture plate electrically connected to the second electrical contact area on the second side of the substrate substantially opposite the first electrical contact area of the substrate.

These and other objects and advantages of the invention will become apparent to those skilled in the art from the following detailed description of the invention and the accompanying drawings.

### BRIEF DESCRIPTION OF THE DRAWINGS

FIG. 1 illustrates a conventional test probe interface with capacitors and resistors assembled on a printed circuit board (PCB).

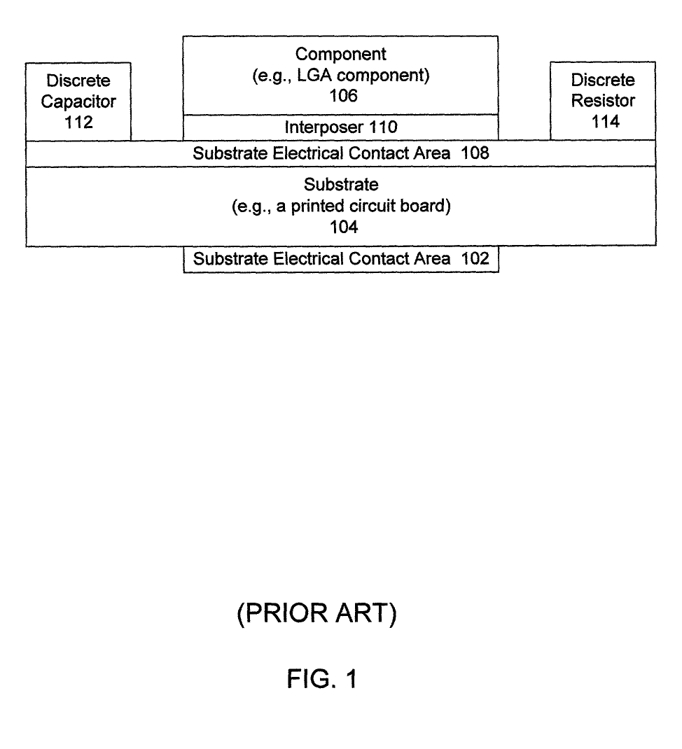

FIG. 2 illustrates a substrate and data capture plate assembly according to one embodiment of the invention.

FIG. 3 illustrates one embodiment of a data capture plate composed of alternating layers of dielectric layers, conductive ground planes, and conductive power planes.

FIG. 4 illustrates one embodiment of a data capture plate and a processor component clamped by a mechanical press into Thomas and Betts sockets on opposite sides of a substrate, according to one embodiment of the invention.

FIG. 5 shows one flow chart for a method to assemble a data capture plate on a substrate as shown in FIG. 2 in accordance with one embodiment of the present invention.

FIG. 6 shows a flow chart for a method to fabricate a data capture plate in accordance with one preferred embodiment of the present invention.

### DETAILED DESCRIPTION OF PREFERRED EMBODIMENTS OF THE INVENTION

The present invention provides a data capture plate with an improved resistance and capacitance that is closer to the IC components on a substrate. This data capture plate is attached after an electrical component is mounted on the substrate, such as a printed circuit board (PCB) or multi-chip module. While the discussion below is directed to an application of the invention to a land grid array (LGA) or ball grid array (BGA) component assembled on a substrate (e.g., a PCB), the invention can also be applied to other types of electrical components assembled on other substrates (e.g., multi-chip modules, and flexible substrates).

A data capture plate assembly is a passive, loadable, PCB structure that provides capacitance (e.g., decoupling capacitance) and resistance (e.g., test probe isolation resistance) to the pads in a LGA or BGA component pattern. Originally designed to take advantage of test-points used for In-Circuit Testing (ICT) testing, the data capture plate assembly locates capacitance and resistance near the pins of large LGA or BGA components as closely as physically possible. Since stray inductance is the primary reason for a reduction in the effectiveness of discrete capacitors and discrete resistors at higher frequencies, shortening the electrical distance from the test probe interface capacitance and resistance to the component pins dramatically reduces the detrimental effects of inductance on an electrically connected test probe interface.

The data capture plate is designed to provide very high, distributed capacitance compared to capacitance provided by discrete capacitors. For example, a capacitance of approximately 6 nanoFarads (nF)/inch² (i.e., approximately 1 nF/cm²) can be achieved with a parallel plate structure of 20 layers of power planes and ground planes separated by layers of 3 mils thick conventional PCB fiberglass (FR4). Fewer layers, or alternatively a higher capacitance board, can be achieved with a dielectric material with a higher dielectric constant (e.g., EmCap® dielectric material, having a relative permittivity (εᵣ) approximately equal to 50, available from Sanmina Corporation, with corporate headquarters in San Jose, Calif.; and Semiconductor Supercapacitor System (S₃) material, available from Energenius, Inc., with corporate headquarters in North York, Ontario, Canada).

A data capture plate with low inductance resistance can be achieved by incorporating buried resistors inside the data capture plate, with the buried resistors made from resistive thin film materials (e.g., Ohmega-Ply® material, which is available from Ohmega Technologies, Inc., with corporate headquarters in Culver City, Calif.). In alternative embodiments, in addition to the capacitance and resistance internally provided by the data capture plate, discrete capacitors can be loaded on one side of the data capture plate to provide additional capacitance.

One preferred mechanical construction for a LGA component attachment is a pressure fit, solder-less one in which a socket (e.g., a Thomas and Betts socket available from Thomas and Betts, with corporate headquarters in Memphis, Tenn.; or an equivalent socket) is used. A data capture plate assembly can be assembled on the opposite side of the substrate underneath a LGA or BGA component, connected by a socket (e.g., identical to the LGA component socket), or connected by soldering (for long term testing). In either case, a data capture plate provides a better high-frequency test probe interface than the use of discrete capacitors and discrete resistors on the substrate. Finally, a data capture plate assembly takes advantage of the PCB test-point areas under the LGA or BGA components that are normally a “waste of space” after the ICT process finishes.

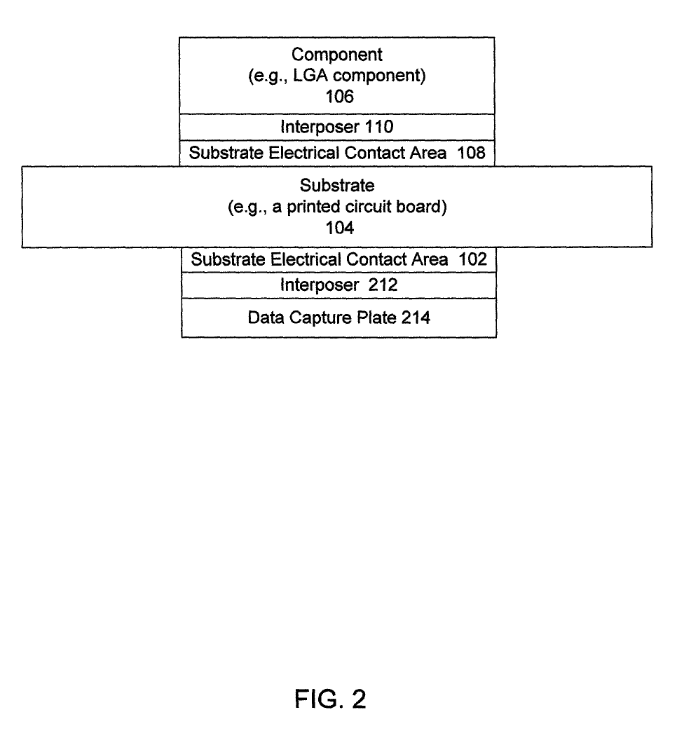

FIG. 2 illustrates a substrate and a data capture plate assembly according to one embodiment of the invention. Here, a LGA component 106 is assembled on a substrate 104, and electrically connected to the substrate 104 through an interposer 110 {e.g., a socket, an elastomeric pad (e.g., a rubber, a plastic, or an equivalent polymeric material) with conductive vias, or an equivalent connector} and a substrate electrical contact area 108. On the other side of the substrate 104 is a data capture plate 214 electrically connected to the substrate 104 through an interposer 212 and a substrate electrical contact area 102.

In an alternative embodiment, the data capture plate 214 can be directly soldered to the substrate 104. In another embodiment, the data capture plate 214 is directly substituted on the substrate for a capacitor plate that provides decoupling capacitance to the substrate. Embodiments of capacitor plates are disclosed in the co-pending U.S. patent application entitled “Capacitor Plate for Substrate Components,” filed on May 18, 2001, by the common assignee, which is incorporated by reference.

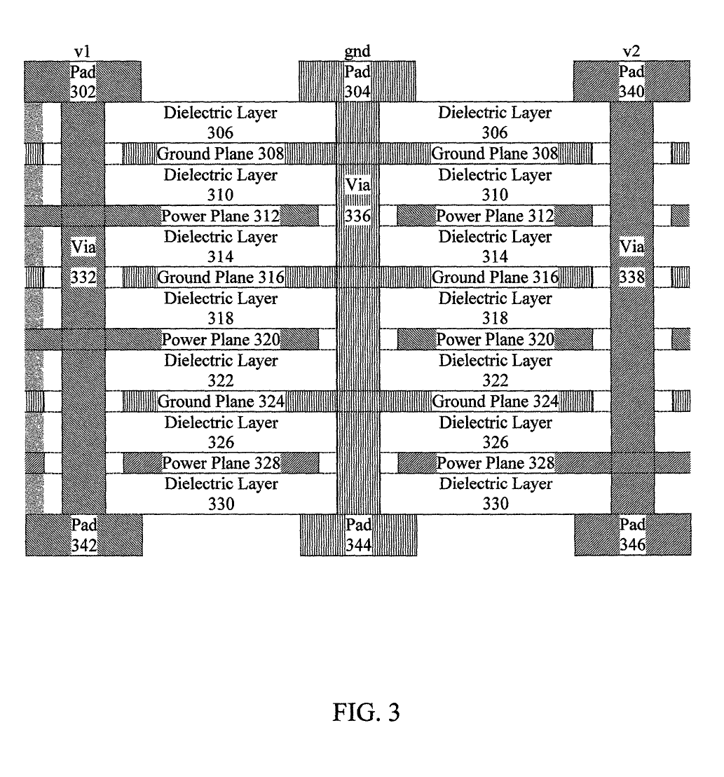

FIG. 3 illustrates one embodiment of a data capture plate 214 composed of alternating layers of dielectric layers 306, 310, 314, 318, 322, 326, and 330; ground planes 308, 316, and 324; and power planes 312, 320, and 328. Contact pads 302 and 342 are connected by via 332 to power planes 312 and 320; contact pads 304 and 344 are connected by via 336 to ground planes 308, 316, and 324; and contact pads 340 and 346 are connected by via 338 to power plane 328. Since power planes 312 and 320 are surrounded by dielectric layers 310, 314, 318, and 322, which in turn are surrounded by ground planes 308, 316 and 324, the capacitance created between contact pad 302 and contact pad 304 is twice as much as would be created if the contact pad 302 was only connected to power plane 312.

The data capture plate 214 is fabricated from alternating layers of conductors and dielectric layers chosen from the following materials: FR4, a resin, an elastomeric material (e.g., a rubber, a plastic, or an equivalent polymeric material), or a ceramic. One preferred embodiment of the invention has a data capture plate fabricated from alternating layers of copper and FR4. In another embodiment, the data capture plate 214 includes a metal reinforcement layer to counteract a large perpendicular clamping force to provide flatness and rigidity to the PCB 104, and provide a uniform load distribution across the contact region of a LGA component 106.

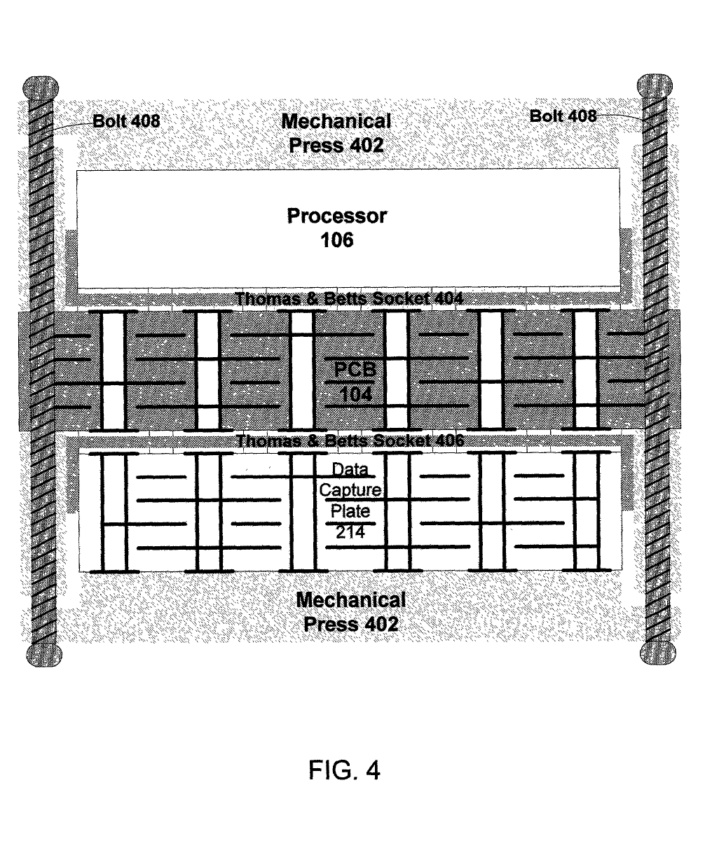

FIG. 4 illustrates one embodiment of a data capture plate 214 and a processor component 106 clamped by a mechanical press 402 into Thomas and Betts sockets 404 and 406 on opposite sides of a PCB substrate 104, according to one embodiment of the invention. The mechanical press 402 includes bolts 408 that are inserted through the PCB substrate 104.

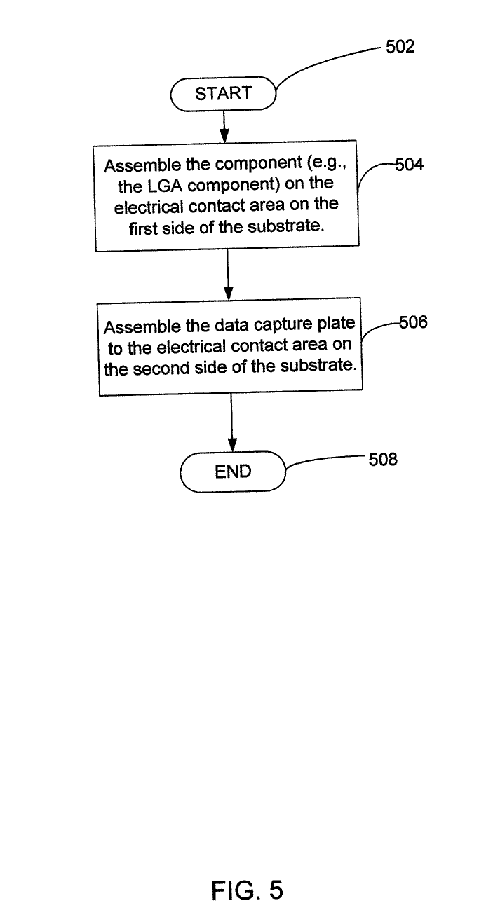

FIG. 5 shows one flow chart for a method to assemble a data capture plate on a substrate as shown in FIG. 2 in accordance with one embodiment of the present invention. The method starts in operation 502, and is followed by operation 504. In operation 504, a component is attached to the electrical contact area on one side of the substrate. For example, a LGA component is electrically connected to the substrate by an interposer. Alternatively, a BGA component is electrically connected to the substrate by re-flowing solder on corresponding pads of the substrate. Operation 506 is next, where a data capture plate is attached to the other side of the substrate (in one embodiment replacing a capacitor plate disclosed in the previously referenced co-pending U.S. patent application entitled “Capacitor Plate for Substrate Components”), and the data capture plate is attached opposite an electrical contact area on the other side of the substrate. Operation 508 is the end of the method.

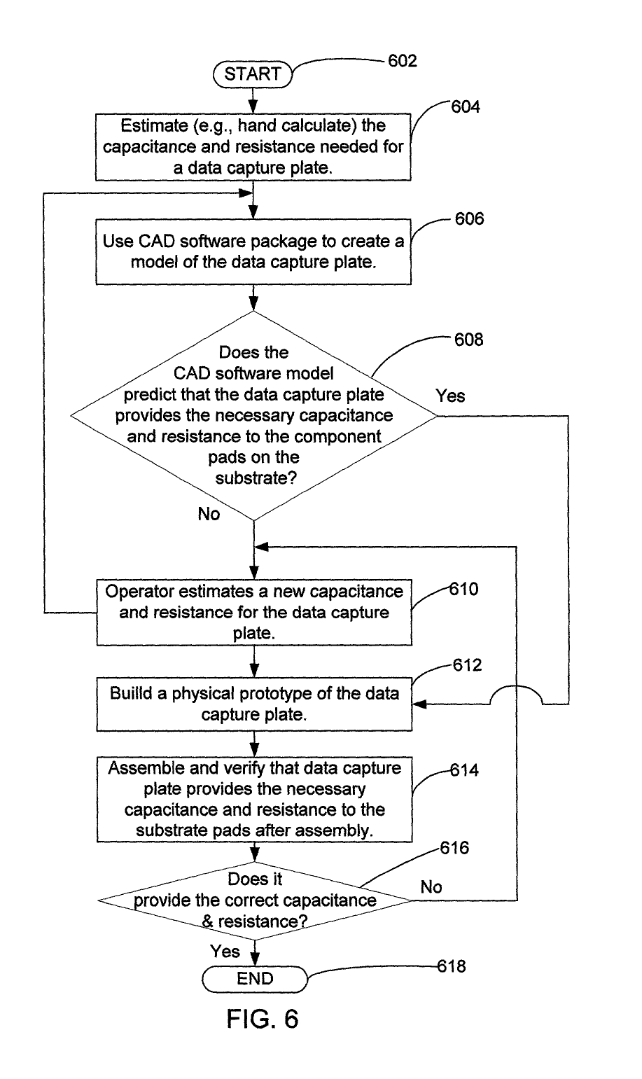

FIG. 6 shows a flow chart for a method to fabricate a data capture plate in accordance with one preferred embodiment of the present invention. The method starts in operation 602, and is followed by operation 604. In operation 604, a hand calculation is made of the capacitance and resistance that needs to be provided by the data capture plate when it is assembled on a substrate. In operation 606, a 3-D computer aided design (CAD) software package (e.g., PSpice®, available from Cadence Design Systems, Inc., with corporate headquarters at San Jose, Calif.; or an equivalent CAD package) is used to create an electrical model of the data capture plate. Then operation 608 is next. In operation 608, a test is made to determine if the CAD software package predicts that that the data capture plate provides the necessary capacitance and resistance for the contact pads under the IC component after assembly. If the test of operation 608 determines that the data capture plate will not provide the correct capacitance and resistance, operation 610 is next where the operator decides on a new capacitance and resistance for the data capture plate. Then operations 606 and 608 are repeated. If the test of the operation 608 determines that the data capture plate will provide the correct capacitance and resistance for the contact pads of the IC component, then operation 612 is next. In operation 612 a physical prototype of the data capture plate is fabricated. Operation 614 is next, where the data capture plate is assembled to the substrate to verify that the data capture plate will provide the correct capacitance and resistance to the contact pads on the substrate under the IC component. Then operation 616 is next, where a test is made to determine if the data capture plate provides the correct capacitance and resistance. If the test of operation 616 verifies that data capture plate does not provide the correct capacitance and resistance, then operation 610 is next. If the test of operation 616 verifies that the data capture plate provides the correct capacitance and resistance, then the method ends in operation 618.

An alternative method of data capture plate fabrication uses discrete resistors held in place by a frame, instead of buried resistors. However, this data capture plate requires an additional Thomas and Betts interposer socket, and this type of data capture plate is subject to poor mechanical contacts due to thermal contractions of the resistors.

The embodiments of the invention discussed above mainly described examples of substrates assembled with data capture plates providing capacitance and resistance for test probe interfaces for LGA or BGA components. However, alternative embodiments of the invention can be applied to other components (e.g., unclamped or clamped IC components, transformers, power supplies, connectors, or other devices that can benefit from having a test probe interface with low inductance).

The exemplary embodiments described herein are for purposes of illustration and are not intended to be limiting. Therefore, those skilled in the art will recognize that other embodiments could be practiced without departing from the scope and spirit of the claims set forth below.

What is claimed is:

1. A method to assemble a data capture plate to one side of a substrate having a first side and a second side, and a first electrical contact area on said first side, and a second electrical contact area on said second side, comprising:
connecting a component to said first electrical contact area on said first side of said substrate; and
connecting said data capture plate to said second electrical contact area on said second side, opposite said first electrical contact area on said first side of said substrate.

2. The method of claim 1, further comprising:
attaching a first interposer to said first electrical contact area on said first side of said substrate;
attaching said component to said first interposer on said first electrical contact area on said first side of said substrate;
attaching a second interposer to said second electrical contact area on said second side of said substrate; and
attaching said data capture plate to said second interposer.

3. The method of claim 2, wherein said first interposer and said second interposer are chosen from a group of interposers consisting of: a socket, or a conductive elastomeric material.

4. The method of claim 1, wherein said component is chosen from a group of components consisting of: a land grid array (LGA) component, or a ball grid array (BGA) component.

5. The method of claim 1, wherein said substrate is chosen from a group of substrates consisting of: a printed circuit board (PCB), a multi-chip module (MCM), and a flexible substrate.

6. The method of claim 1, wherein said data capture plate comprises:
a plurality of conductive planes; and
one or more dielectric layers to separate said plurality of conductive planes, wherein said one more dielectric layers include a material consisting of: FR4, a resin, an elastomeric material, or a ceramic.

7. The method of claim 1, wherein said data capture plate is attached by solder to said second electrical contact area on said second side of said substrate.

8. A method to fabricate a data capture plate, comprising:
selecting a set of physical specifications of said data capture plate;
estimating an initial required capacitance and resistance for a plurality of contacts on said data capture plate;
modeling said data capture plate after assembly on a substrate;
estimating a more precise required capacitance and resistance for said plurality of contacts on said data capture plate after modeling said data capture plate after assembly on said substrate; and
fabricating said data capture plate according to said set of physical specifications.

9. The method of claim 8, wherein said data capture plate includes one or more layers including a material consisting of: FR4, a resin, an elastomeric material, a ceramic, or a resistive thin film.

10. The method of claim 8, wherein said data capture plate includes soldering pads for soldering said data capture plate to said substrate.

11. The method of claim 8, wherein said data capture plate comprises:
a plurality of power planes; and
a plurality of ground planes, wherein said plurality of power planes and said plurality of ground planes are separated by one or more dielectric layers including a dielectric layer chosen from the materials consisting of: FR4, a resin, an elastomeric material, or a ceramic.

12. The method of claim 8, wherein said data capture plate has one or more layers of dielectric material with a relative permittivity greater than 4.

13. An assembled substrate, including a data capture plate, comprising
a substrate having a first side and a second side, and a first electrical contact area on said first side and a second electrical contact area on said second side;
an electrical component having a plurality of leads electrically connected to said first electrical contact area of said substrate; and
a data capture plate electrically connected to said second electrical contact area on said second side of said substrate substantially opposite said first electrical contact area of said substrate.

14. The assembled substrate of claim 13, wherein said assembled substrate further comprises:
a first interposer between said component and said first electrical contact area on said first side of said substrate; and
a second interposer between said data capture plate and said second electrical contact area on said second side of said substrate.

15. The assembled substrate of claim 14, wherein said first interposer and said second interposer are chosen from a group of interposers consisting of: a socket, or a conductive elastomeric material.

16. The assembled substrate of claim 13, wherein said substrate is chosen from a group of substrates consisting of: a PCB, a MCM, and a flexible substrate.

17. The assembled substrate of claim 13, wherein said component is chosen from a group of components consisting of: a LGA component, or a BGA component.

18. The assembled substrate of claim 13, wherein said data capture plate has a plurality of layers of dielectric material separating a plurality of layers of conductive material, and includes a buried resistor layer.

19. The assembled substrate of claim 13, wherein said data capture plate comprises:
a plurality of power planes; and
a plurality of ground planes, wherein said plurality of power planes and said plurality of ground planes are separated by one or more dielectric layers including a dielectric layer chosen from the materials consisting of: FR4, a resin, an elastomeric material, or a ceramic.

20. The assembled substrate of claim 13, wherein said data capture plate is attached by solder to said second electrical contact area on said second side of said substrate.
